(19) United States
(12) Patent Application Publication
(10) Pub. No.: US 2011/0228948 A1
(43) Pub. Date: Sep. 22, 2011

(54) SYSTEMS AND METHODS FOR PROCESSING AUDIO DATA

(76) Inventor: Geoffrey Engel, West Pymble (AU)

(21) Appl. No.: 13/052,351

(22) Filed: Mar. 21, 2011

(30) Foreign Application Priority Data
Mar. 22, 2010 (AU) 2010901204

(51) Int. Cl. H03G 5/00; H04R 1/10

(52) U.S. Cl. 381/74; 381/98

(57) ABSTRACT

Described herein are systems and methods for processing audio data. For example, one embodiment provides a device configured to receive an audio signal, and process that audio signal based on a frequency mapping protocol, thereby to provide a modified audio signal. The resulting modified signal is audibly communicated to a user. In overview, the frequency mapping protocol allows components of an audio signal that within specified frequency ranges to be mapped to other frequency ranges, attenuated, or in some cases blocked altogether. The user is also able, at least in some embodiments, to use the same device to perform testing of their hearing. In some embodiments the frequency mapping protocol is modifiable by a user, for example by way of a software application running on a PC or other computational platform. This allows a significant degree of flexibility in terms of the device's operation; a user is effectively able to customize the device for his/her specific hearing requirements. For example, in the case of a partially deaf person, frequencies that could not otherwise be heard are mapped to frequencies that can be heard. In the case of a person working in a noisy environment, frequencies that are too loud (for example frequencies from particular machinery) can be terminated or attenuated.

### FIELD OF THE INVENTION

The present invention relates to systems and methods for processing audio data. Embodiments of the invention have been particularly developed for to provide a device that allows frequency-based mapping of audio substantially in real time, thereby to enhance the hearing of a user. Although the invention is described hereinafter with particular reference to such applications, it will be appreciated that the invention is applicable in broader contexts.

### BACKGROUND

Any discussion of the prior art throughout the specification should in no way be considered as an admission that such prior art is widely known or forms part of common general knowledge in the field.

There are a number of devices on the market with the specific purpose of improving the hearing of users. These range from simple amplifiers to complex hearing aids and implantable devices. Traditionally, the focus has been on improving the ability to hear in terms of amplification and/or neurostimulation. Whilst these are certainly important and useful functionalities, they are not necessarily well suited to all hearing problems.

It follows that there is a need in the art for improved systems and methods for processing audio data.

### SUMMARY

It is an object of the present invention to overcome or ameliorate at least one of the disadvantages of the prior art, or to provide a useful alternative.

One embodiment provides a device for processing audio data, the device including:

an input for receiving an audio signal, and based on the received audio signal providing an analogue electrical audio signal;

an ADC configured for converting the electrical analogue audio signal into a digital audio signal;

a processor configured to:

apply a time-to-frequency transformation to the digital audio signal, thereby to define a frequency domain signal;

modify the frequency domain signal based on a frequency mapping protocol, thereby to define a modified frequency domain signal;

apply a frequency-to-time transformation to the modified frequency domain signal, thereby to define a modified digital audio signal;

a DAC configured for converting the modified digital audio signal into a modified analogue audio signal; and

an output for providing the modified analogue audio signal.

One embodiment provides a method for controlling the processing of audio data, the method including:

providing an interface for allowing a user to define rules for modifying the behaviour of audio data within a predefined selection of frequency bands;

defining configuration data indicative of a frequency mapping protocol based on the rules defined;

providing a signal indicative of the configuration data for download to a device that processes audio data.

One embodiment provides a non-transitive computer readable medium containing code that, when executed on one or more processors, causes the processors to perform a method as described herein.

One embodiment provides an executable computer program product configured to perform a method as described herein.

One embodiment provides a device configured to:

receive an audio signal;

split the audio signal into frequency bands;

map one or more of the frequency bands to other frequency bands; and

provide an audio signal wherein the one or more of the frequency bands are mapped to other frequency bands.

Reference throughout this specification to “one embodiment” or “an embodiment” or “some embodiments” means that a particular feature, structure or characteristic described in connection with the embodiment is included in at least one embodiment of the present invention. Thus, appearances of the phrases “in one embodiment” or “in an embodiment” or “in some embodiments” in various places throughout this specification are not necessarily all referring to the same embodiment, but may. Furthermore, the particular features, structures or characteristics may be combined in any suitable manner, as would be apparent to one of ordinary skill in the art from this disclosure, in one or more embodiments.

### BRIEF DESCRIPTION OF THE DRAWINGS

Embodiments of the invention will now be described, by way of example only, with reference to the accompanying drawings in which:

FIG. 1 schematically illustrates a device according to one embodiment.

FIG. 2 schematically illustrates a device according to one embodiment.

FIG. 3 is a screenshot from an exemplary software application according to one embodiment.

FIG. 4 is a screenshot from an exemplary software application according to one embodiment.

FIG. 5 is a screenshot from an exemplary software application according to one embodiment.

FIG. 6 is a screenshot from an exemplary software application according to one embodiment.

FIG. 7 schematically illustrates a device according to one embodiment.

### DETAILED DESCRIPTION

Described herein are systems and methods for processing audio data. For example, one embodiment provides a device configured to receive an audio signal, and process that audio signal based on a frequency mapping protocol, thereby to provide a modified audio signal. The resulting modified signal is audibly communicated to a user. In overview, the frequency mapping protocol allows components of an audio signal that within specified frequency ranges to be mapped to other frequency ranges, attenuated, or in some cases blocked altogether. In some embodiments the frequency mapping protocol is modifiable by a user, for example by way of a software application running on a PC or other computational platform. This allows a significant degree of flexibility in terms of the device's operation; a user is effectively able to customize the device for his/her specific hearing requirements. For example, in the case of a partially deaf person, frequencies that could not otherwise be heard are mapped to frequencies that can be heard. In the case of a person working in a noisy environment, frequencies that are too loud (for example frequencies from particular machinery) can be terminated or attenuated.

### General Overview

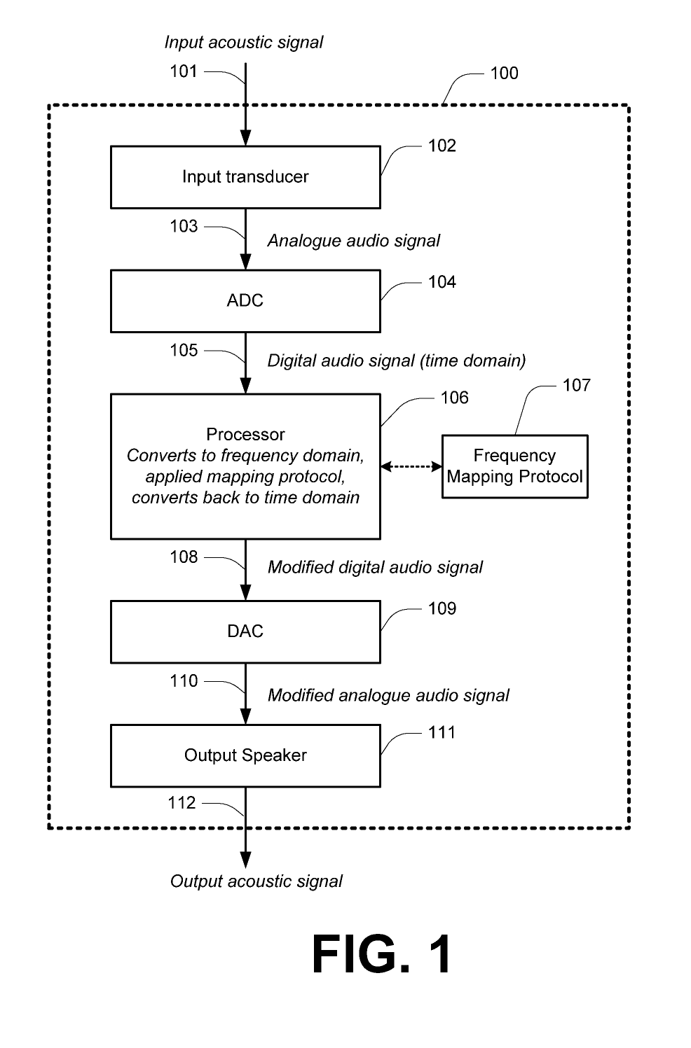

FIG. 1 illustrates a device 100 according to one embodiment. This figure provides a simplified representation of an exemplary device for the purposes of providing a general overview of the technology.

Device 100 receives an acoustic signal 101 at an input 102, which in this instance takes the form of an acousto-electric transducer, such as an electret or a condenser microphone, or the like.

Input 102 provides an electrical analogue audio signal 103 to an analogue to digital converter (ADC) 104. ADC 104 concerts the analogue signal into a digital form, thereby to provide a digital audio signal 105, being a time domain signal.

Signal 105 is processed at a processor 106. In some embodiments processor 106 is defined by or includes a DSP processor, a FPGA, or similar component. Processor 106 is configured to apply a time-to-frequency transformation to the digital audio signal, thereby to define a frequency domain signal, for example through the application of a Fourier transform. Processor 106 is additionally configured to modify the frequency domain signal based on a frequency mapping protocol 107, thereby to define a modified frequency domain signal. Subsequently, the processor applies a frequency-to-time transformation to the modified frequency domain signal (typically using an inverse Fourier transform), thereby to define a modified digital audio signal 108.

A digital to analogue converter (DAC) 109 is configured for converting modified digital audio signal 108 into a modified analogue audio signal 110. This analogue signal is provided to an output, presently in the form of an output speaker 111, which provides an output acoustic signal 112.

Frequency mapping protocol 107 is optionally stored in memory of device 100, such as non-volatile memory. Furthermore, in some embodiments, frequency mapping protocol 107 is modifiable by a user thereby to adjust the operation of device 100.

As general context, device 100 is optionally implemented to modify signal 101 such that a user hears signal 112 in preference to signal 101. That is, rather than hearing signal 101, a user hears signal 112, being a modified signal based on frequency mapping protocol 107. In overview, the frequency mapping protocol defines a set of rules for modifying the behavior of components of the frequency domain signal. For example, frequency domain signal is split into a plurality of bands, each band corresponding to a frequency range, and the frequency mapping protocol defines rules for modifying the behavior of one or more of the bands. The rules for modifying one or more of the bands may includes a rule for mapping components of the frequency domain signal from a first band to a second band. Additionally, the rules for modifying one or more of the bands may include a rule for blocking components of the frequency domain signal that fall within a specified one or more bands.

### Exemplary Device

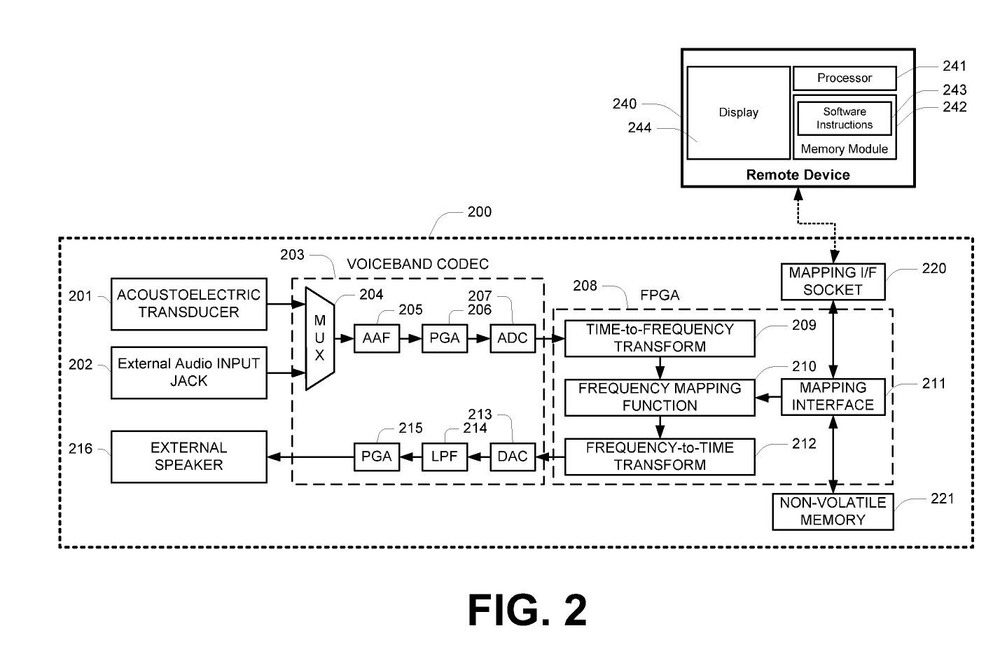

FIG. 2 illustrates a device 200 according to one embodiment. This device is fairly similar to device 101, but shown with additional detail and functionality.

Device 200 includes two inputs, being an acousto-electric transducer 201 for receiving acoustic signals and converting those to electrical signals, and an external input audio jack 202 for receiving electrical signals, for example from an external device such as an MP3 player or the like. The signals from transducer 201 and jack 202 are provided to a voiceband codec 203. In particular, the signals are passed into a multiplexer 204, then to an anti aliasing filter 205, a programmable gain amplifier 206, and then to an ADC 207. This provides a digital representation of the audio data.

The digital audio data is processed by a FPGA 208, or other appropriate processing equipment. FPGA 208 provides a time-to-frequency transform 209, for converting the time-domain signals received from ADC 207 to frequency domain signals. These frequency domain signals are then modified by a frequency mapping function 210. This determines how one or more of the frequency bands in the frequency domain signal and their corresponding amplitudes are modified based on a frequency mapping protocol. Frequency mapping function 210 operates under the control of a mapping interface 211, as discussed further below.

Following modification by frequency mapping function 210, the resulting modified frequency domain signals are converted back into time domain by a frequency-to-time transform 212. The resulting signal is then converted back to analogue form by a DAC 213, passed though a low-pass filter 214 and programmable gain amplifier 215, and then outputted by an external speaker 216.

As noted, frequency mapping function 210 operates under the control of a mapping interface 211. In overview, the operation of the mapping function 210 is able to be modified by a user. In the present embodiment, configuration data indicative of a frequency mapping protocol based on user-defined rules is received via a mapping interface port 220, and stored in non-volatile memory 221. The nature of port 220 varies between embodiments, and may include a USB connection, serial connection, wireless connection, or the like. The general crux is that port 220 allows device 200 to interface with an external device, such as a PC or other computational platform, thereby to allow a user to modify the operation of frequency mapping function 210. This is described in additional detail in the following section.

In some embodiments device 200 is embodied in or integrated/interfaced with a standalone portable unit, such as a set of headphones. For example, one embodiment visually resembles a set of headphones, although these are modified to include a microphone and requisite internal circuitry between the microphone and speakers.

### Exemplary Mapping Interface Control

FIG. 2 also illustrates a remote device 240 configured for interaction with device 200. Device 240 includes a processor 241 coupled to a memory module 242, this memory module maintaining software instructions 243. These software instructions allow for a user interface to be displayed on a display 244. In this manner, device 244 is generically descriptive of a wide range of computational devices, including PCs, PDAs, cellular telephones, and the like.

Software instructions 243 are executed via processor 241 for allowing the execution of a computer program product and performance of various methods described herein. One such method includes providing an interface (via display 244) for allowing a user to define rules for modifying the behaviour of audio data within a predefined selection of frequency bands. Based on this, the method includes defining configuration data indicative of a frequency mapping protocol that applies those rules. The method further includes providing a signal indicative of the configuration data for download to a device that processes audio data. In the context of FIG. 2, this configuration data is downloaded and stored in memory 221, such that frequency mapping function 210 subsequently operates on the basis of the user defined rules.

In essence, device 200 operates based on a frequency mapping protocol, which defines a set of rules for modifying the behaviour of components of the frequency domain signal. In the present embodiment, these components are defined by reference to frequency bands. For example, a first frequency band is defined for frequencies between A Hz and B Hz, a second frequency band for frequencies between B Hz and C Hz, and a third frequency band for frequencies between C Hz and D Hz. The frequency mapping protocol defines rules for modifying the behavior of one or more of the bands. For example, the rules might stipulate that components of the frequency domain signal that fall in the first frequency band are to be mapped into the second frequency band, and/or that frequency domain signal that fall in the third frequency band are to be attenuated or blocked.

In terms of frequency bands, in some embodiments the full spectrum of audible frequencies (e.g. from 0 to 12 kHz) is broken up into a plurality of bands. The number of bands varies between embodiments. For example, some embodiments make use of between 20 and 200 bands, and other embodiments between 20 and 4,000 bands. In one example, there are 64 bands, each covering a range of 185 Hz. It will be appreciated that as the number of bands increases, there is allowance for finer control of the frequency mapping function.

The rules may include the likes of:
A rule for mapping components of the frequency domain signal from a first band to a second band. This, in essence, allows the re-mapping of input frequencies band(s) to desired output frequency band(s). Such functionality is particularly useful where a user has hearing difficulties within a particular one or more frequency bands. Audio having frequency components within those problematic bands is mapped such that the relevant audio has frequency outside of the problematic bands, hence greatly assisting the user in hearing.
A rule for blocking (completely or partially) components of the frequency domain signal that fall within a specified one or more bands. This is particularly useful in situations where a user is exposed to loud noises within a particular frequency range; those are effectively attenuated or blocked thereby allowing the user to hear other sounds, and otherwise protect the user's hearing.

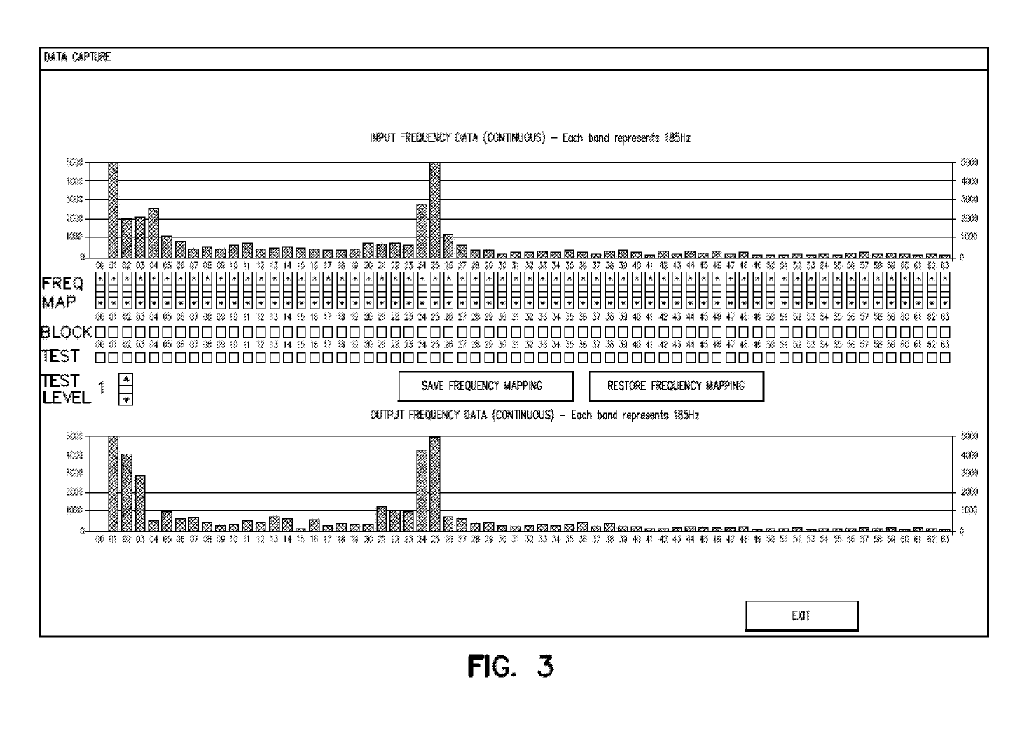

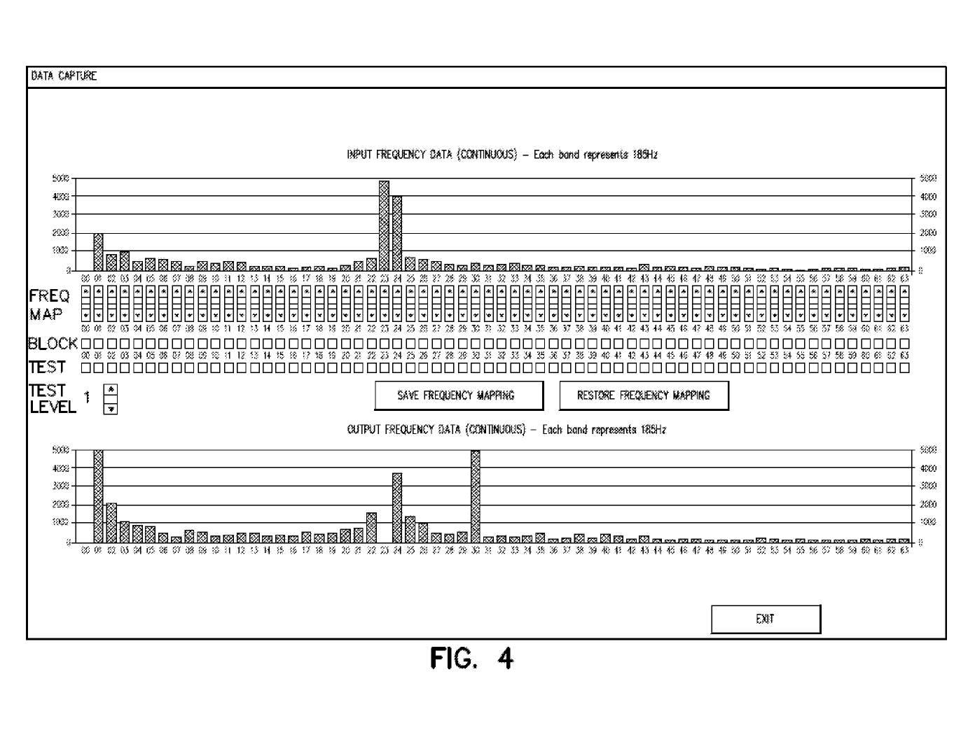

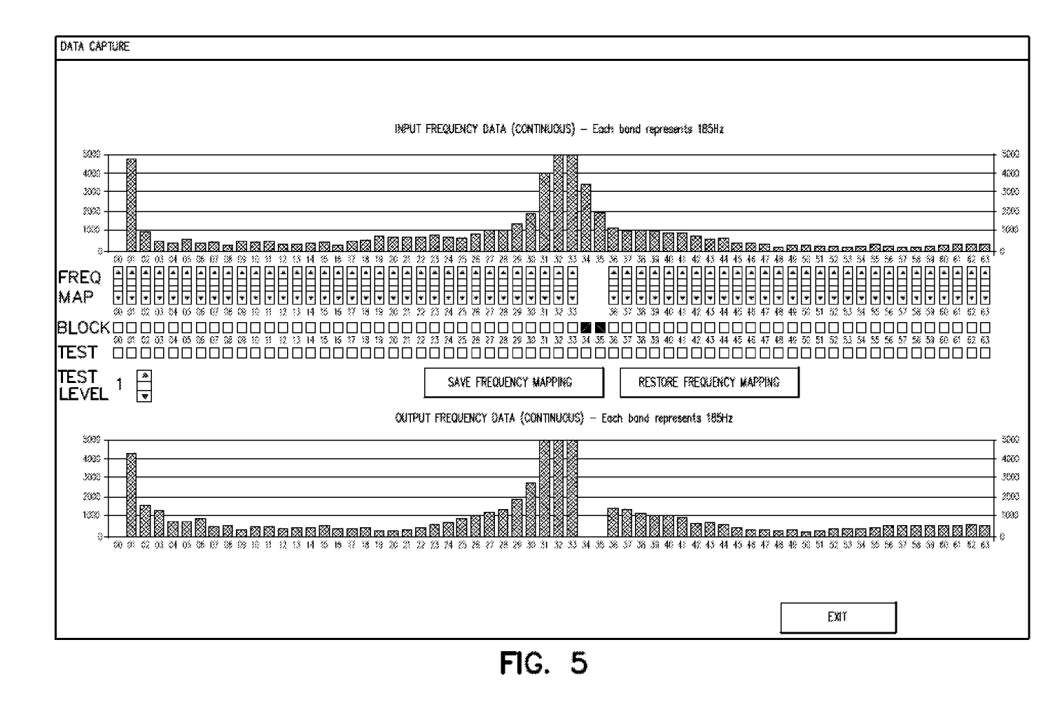

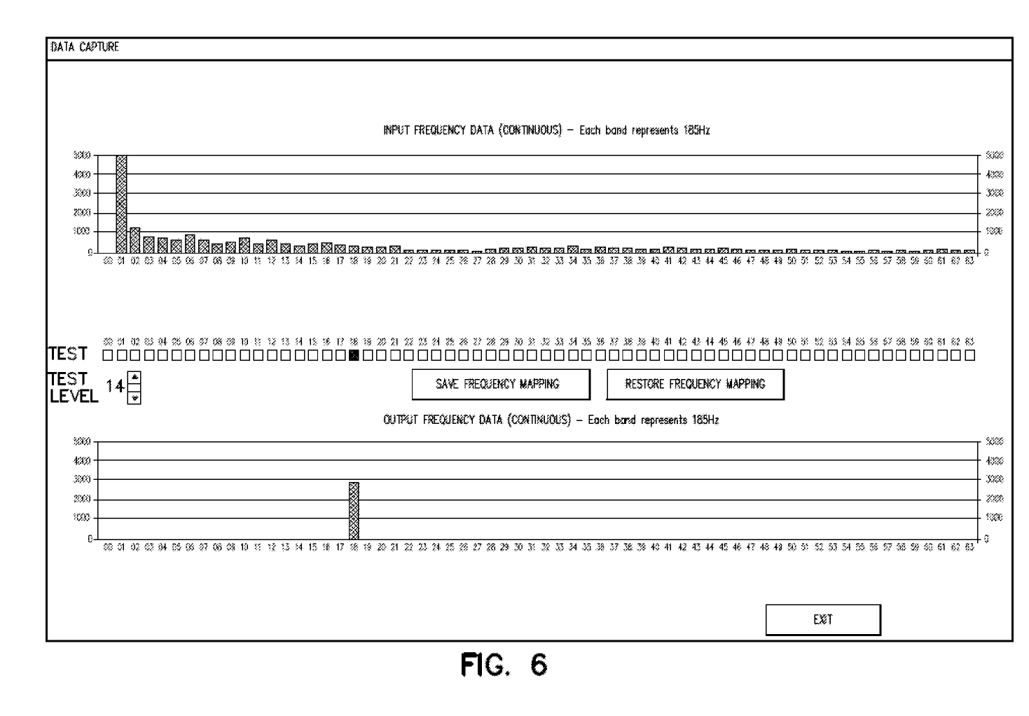

FIGS. 3, 4, 5 and 6 provide screenshots from an exemplary software interface for allowing modification of a frequency mapping protocol. In these, there are 64 frequency bands, each covering a range of 185 Hz. Two charts are provided thereby to allow convenient visualization of the frequency bands as they change in real-time; an upper chart showing input frequencies, and a lower chart showing output frequencies. The screenshots show the following:
FIG. 3 shows a 1-to-1 input-to-output mapping of a tone around 4600 Hz, with no blocking.
FIG. 4 shows the remapping of band 23 to band 30 (moving 4200 Hz tones to 5500 Hz), with no blocking
FIG. 5 shows the 1-to-1 input-to-output mapping with blocking of bands 34 and 35, so that these frequencies are lost to the sounds actually heard by the user.
FIG. 6 shows the testing of band 18 (3300 Hz) only on the user. The output test level is adjustable. When testing is occurring then mapping is ignored.

In terms of FIG. 6, an additional functionality provided by the present software interface is the testing of particular frequency bands on users, thereby to assist in the diagnosis of problematic frequency bands. For example, the software interface is programmed to cause the emission of audible tones at specified frequencies. This is useful in guiding a user through the process of defining rules appropriate for their particular circumstances (for example it assists a user identify frequencies that are difficult to hear due to a notched range of hearing or the like). In some embodiments the software comes pre-loaded with a set of sample mapping protocols, which may be used in their existing forms or modified for fine tuning purposes.

Although the implementation of the present screenshots has only 64 bands, some embodiments have a greater number of bands, for example as many as 512 frequency bands. However, this is more difficult to configure from an end-user perspective (due, for example, to visualization challenges). Despite this, such embodiments provide much greater control & flexibility, and the finer resolution of frequency bands may give improved sound to the user.

Another feature includes the ability to adjust (or scale) the level of each individual input frequency band, subsequent to any mapping or termination—and before transmission to the user.

In some embodiments the software interface is configured for allowing configuration of mapping for each ear separately, noting that many people have better hearing in one ear than the other.

### Implementation Comments

Experimental results have verified that using 24 MHz operation of a FPGA (which is relatively slow by current standards) allows the performance of a 128-point time-to-frequency calculation (via fast Fourier transform), mapping of data based on a frequency mapping protocol, and 128-point frequency-to-time transform (via inverse fast Fourier transform) to be performed in approximately 0.1 milliseconds. Furthermore, it has been recognized that existing codecs are capable of performing 16-bit A/D and 16-bit D/A conversion every 43 microseconds (23.4 kHz). Accordingly, the performance of a device as presently described is readily able to be considered as close to real-time in terms of processing latency as observed by a user.

Each stage of the design can incorporate automatic gain control (AGC) to ensure that a nominal level is maintained throughout operation, and no clipping of the data occurs. This maintains maximum dynamic range of operation. This AGC operation may be selectable (enable/disable) by the user via the user interface.

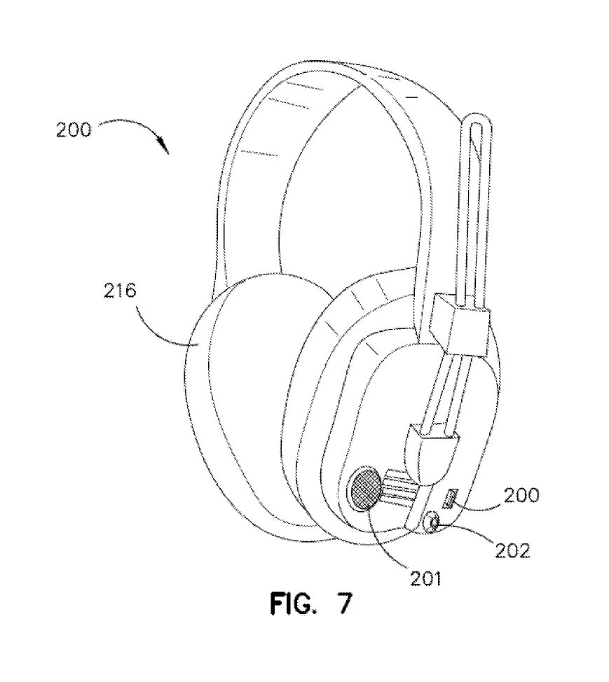

One embodiment takes the form of a closed ear headphone, as shown in FIG. 7. The use of closed ear headphones provides maximum auditory isolation between the incident sound signals and the re-mapped sound signals, which are transmitted to the user's ears via the headphone speakers. In each side of the speakers, there is an acousto-electric transducer to receive incident acoustic signals. There is also an audio jack for receiving signals from a device such as an MP3 player or the like. A mapping port allows the headphones to be connected to and external device for configuration of the mapping protocol. The headphones internally include circuitry and batteries to provide other functionalities described herein. In some cases the two transducers are processed independently to their respective speakers, thereby to assist in directional hearing. In some cases different mapping protocols are applied for the left and right ears. This can be useful where only one ear has certain problems, or in environments where loud noises predictably occur only on one side of a user.

### Exemplary Applications

Various exemplary applications are described below. It will be appreciated that in some embodiments a device having appropriate hardware and software components is configurable for a plurality of these applications, whereas in other embodiments a device is configured specifically for a particular one or more of these applications.

One application includes mapping frequencies for the purpose of assisting a user with frequency-dependent hearing difficulties. For example, a user may have difficulties with frequencies in a specific range; the device is configured to map those frequencies to another range.

Another application is to assist users working in noisy environments, particularly those where problematic noises tend to fall within set frequencies (for example where machinery is being used). Frequencies that are particularly loud or otherwise problematic to users can be terminated or attenuated. This leaves the user open to hear sounds at other frequencies. For example, this may assist in the carrying out of conversations in the presence of plant equipment.

A further application includes amplifying and frequency-shifting frequencies associated with power sources, for example 50 Hz or 60 Hz radiation from mains power sources. These frequencies are shifted to a frequency which is more easily heard by human ears, thereby to assist in the identification of power sources in walls. For instance, by using a two-ear device, with the same frequency-shifting for each ear, the wearer is enabled to perceive/triangulate locations at which live power sources are likely to be concealed. This is of use prior to drilling or cutting a wall, for example.

In a further application, a device is configured such that ultra-low frequencies (for example frequencies in the order of 10 Hz) are shifted into a range more easily audible for humans. This is useful, by way of example, for listening to the communications of sea mammals such as dolphins and whales.

In a similar manner, another application includes a device configured to amplify and frequency-shift infra-sound (0.1 Hz to 20 Hz) to frequencies which can be heard by humans. These are the frequencies often emitted seconds or minutes prior to an earthquake. This has relevance to early warning systems configured to generate audible-to-humans alarms.

A further example includes a device configured to amplify and frequency-shift high frequencies (for example 20 kHz to 120 kHz) to frequencies which are more easily heard by humans. Such high frequencies are, for example, emitted by bats as part of their echo-location system. By using the same frequency-shifting for each ear, the wearer could perceive/triangulate where the bats are located, and better understand their movements.

### CONCLUSIONS AND INTERPRETATION

It will be appreciated that the above disclosure provides improved systems and methods for processing audio data. For example, the present frequency-based approach allows for a particularly flexible arrangement for improving the hearing of a wide range of users.

Unless specifically stated otherwise, as apparent from the following discussions, it is appreciated that throughout the specification discussions utilizing terms such as “processing,” “computing,” “calculating,” “determining”, analyzing” or the like, refer to the action and/or processes of a computer or computing system, or similar electronic computing device, that manipulate and/or transform data represented as physical, such as electronic, quantities into other data similarly represented as physical quantities.

In a similar manner, the term “processor” may refer to any device or portion of a device that processes electronic data, e.g., from registers and/or memory to transform that electronic data into other electronic data that, e.g., may be stored in registers and/or memory. A “computer” or a “computing machine” or a “computing platform” may include one or more processors.

The methodologies described herein are, in one embodiment, performable by one or more processors that accept computer-readable (also called machine-readable) code containing a set of instructions that when executed by one or more of the processors carry out at least one of the methods described herein. Any processor capable of executing a set of instructions (sequential or otherwise) that specify actions to be taken are included. Thus, one example is a typical processing system that includes one or more processors. Each processor may include one or more of a CPU, a graphics processing unit, and a programmable DSP unit. The processing system further may include a memory subsystem including main RAM and/or a static RAM, and/or Flash, and/or ROM. A bus subsystem may be included for communicating between the components. The processing system further may be a distributed processing system with processors coupled by a network. If the processing system requires a display, such a display may be included, e.g., an liquid crystal display (LCD) or a cathode ray tube (CRT) display. If manual data entry is required, the processing system also includes an input device such as one or more of an alphanumeric input unit such as a keyboard, a pointing control device such as a mouse, and so forth. The term memory unit as used herein, if clear from the context and unless explicitly stated otherwise, also encompasses a storage system such as a disk drive unit or non-volatile storage memory such as Flash. The processing system in some configurations may include a sound output device, and a network interface device. The memory subsystem thus includes a computer-readable carrier medium that carries computer-readable code (e.g., software) including a set of instructions to cause performing, when executed by one or more processors, one of more of the methods described herein. Note that when the method includes several elements, e.g., several steps, no ordering of such elements is implied, unless specifically stated. The software may reside in the hard disk, or may also reside, completely or at least partially, within the RAM and/or within the processor during execution thereof by the computer system. Thus, the memory and the processor also constitute computer-readable carrier medium carrying computer-readable code.

Furthermore, a computer-readable carrier medium may form, or be includes in a computer program product.

In alternative embodiments, the one or more processors operate as a standalone device or may be connected, e.g., networked to other processor(s), in a networked deployment, the one or more processors may operate in the capacity of a server or a user machine in server-user network environment, or as a peer machine in a peer-to-peer or distributed network environment. The one or more processors may form a personal computer (PC), a tablet PC, a set-top box (STB), a Personal Digital Assistant (PDA), a cellular telephone, a web appliance, a network router, switch or bridge, or any machine capable of executing a set of instructions (sequential or otherwise) that specify actions to be taken by that machine.

Note that while some diagrams only show a single processor and a single memory that carries the computer-readable code, those in the art will understand that many of the components described above are included, but not explicitly shown or described in order not to obscure the inventive aspect. For example, while only a single machine is illustrated, the term “machine” or “device” shall also be taken to include any collection of machines that individually or jointly execute a set (or multiple sets) of instructions to perform any one or more of the methodologies discussed herein.

At least one embodiment of various methods described herein is in the form of a computer-readable carrier medium carrying a set of instructions, e.g., a computer program that are for execution on one or more processors, e.g., one or more processors that are part of building management system. Thus, as will be appreciated by those skilled in the art, embodiments of the present invention may be embodied as a method, an apparatus such as a special purpose apparatus, an apparatus such as a data processing system, or a computer-readable carrier medium, e.g., a computer program product. The computer-readable carrier medium carries computer readable code including a set of instructions that when executed on one or more processors cause the a processor or processors to implement a method. Accordingly, aspects of the present invention may take the form of a method, an entirely hardware embodiment, an entirely software embodiment or an embodiment combining software and hardware aspects. Furthermore, the present invention may take the form of carrier medium (e.g., a computer program product on a computer-readable storage medium) carrying computer-readable program code embodied in the medium.

The software may further be transmitted or received over a network via a network interface device. While the carrier medium is shown in an exemplary embodiment to be a single medium, the term “carrier medium” should be taken to include a single medium or multiple media (e.g., a centralized or distributed database, and/or associated caches and servers) that store the one or more sets of instructions. The term “carrier medium” shall also be taken to include any medium that is capable of storing, encoding or carrying a set of instructions for execution by one or more of the processors and that cause the one or more processors to perform any one or more of the methodologies of the present invention. A carrier medium may take many forms, including but not limited to, non-volatile media, volatile media, and transmission media. Non-volatile media includes, for example, optical, magnetic disks, and magneto-optical disks. Volatile media includes dynamic memory, such as main memory. Transmission media includes coaxial cables, copper wire and fiber optics, including the wires that comprise a bus subsystem. Transmission media also may also take the form of acoustic or light waves, such as those generated during radio wave and infrared data communications. For example, the term “carrier medium” shall accordingly be taken to included, but not be limited to, solid-state memories, a computer product embodied in optical and magnetic media, a medium bearing a propagated signal detectable by at least one processor of one or more processors and representing a set of instructions that when executed implement a method, a carrier wave bearing a propagated signal detectable by at least one processor of the one or more processors and representing the set of instructions a propagated signal and representing the set of instructions, and a transmission medium in a network bearing a propagated signal detectable by at least one processor of the one or more processors and representing the set of instructions.

It will be understood that the steps of methods discussed are performed in one embodiment by an appropriate processor (or processors) of a processing (i.e., computer) system executing instructions (computer-readable code) stored in storage. It will also be understood that the invention is not limited to any particular implementation or programming technique and that the invention may be implemented using any appropriate techniques for implementing the functionality described herein. The invention is not limited to any particular programming language or operating system.

Similarly it should be appreciated that in the above description of exemplary embodiments of the invention, various features of the invention are sometimes grouped together in a single embodiment, figure, or description thereof for the purpose of streamlining the disclosure and aiding in the understanding of one or more of the various inventive aspects. This method of disclosure, however, is not to be interpreted as reflecting an intention that the claimed invention requires more features than are expressly recited in each claim. Rather, as the following claims reflect, inventive aspects lie in less than all features of a single foregoing disclosed embodiment. Thus, the claims following the Detailed Description are hereby expressly incorporated into this Detailed Description, with each claim standing on its own as a separate embodiment of this invention.

Furthermore, while some embodiments described herein include some but not other features included in other embodiments, combinations of features of different embodiments are meant to be within the scope of the invention, and form different embodiments, as would be understood by those in the art. For example, in the following claims, any of the claimed embodiments can be used in any combination.

Furthermore, some of the embodiments are described herein as a method or combination of elements of a method that can be implemented by a processor of a computer system or by other means of carrying out the function. Thus, a processor with the necessary instructions for carrying out such a method or element of a method forms a means for carrying out the method or element of a method. Furthermore, an element described herein of an apparatus embodiment is an example of a means for carrying out the function performed by the element for the purpose of carrying out the invention.

In the description provided herein, numerous specific details are set forth. However, it is understood that embodiments of the invention may be practiced without these specific details. In other instances, well-known methods, structures and techniques have not been shown in detail in order not to obscure an understanding of this description.

As used herein, unless otherwise specified the use of the ordinal adjectives “first”, “second”, “third”, etc., to describe a common object, merely indicate that different instances of like objects are being referred to, and are not intended to imply that the objects so described must be in a given sequence, either temporally, spatially, in ranking, or in any other manner.

In the claims below and the description herein, any one of the terms comprising, comprised of or which comprises is an open term that means including at least the elements/features that follow, but not excluding others. Thus, the term comprising, when used in the claims, should not be interpreted as being limitative to the means or elements or steps listed thereafter. For example, the scope of the expression a device comprising A and B should not be limited to devices consisting only of elements A and B. Any one of the terms including or which includes or that includes as used herein is also an open term that also means including at least the elements/features that follow the term, but not excluding others. Thus, including is synonymous with and means comprising.

Similarly, it is to be noticed that the term coupled, when used in the claims, should not be interpreted as being limitative to direct connections only. The terms “coupled” and “connected,” along with their derivatives, may be used. It should be understood that these terms are not intended as synonyms for each other. Thus, the scope of the expression a device A coupled to a device B should not be limited to devices or systems wherein an output of device A is directly connected to an input of device B. It means that there exists a path between an output of A and an input of B which may be a path including other devices or means. “Coupled” may mean that two or more elements are either in direct physical or electrical contact, or that two or more elements are not in direct contact with each other but yet still co-operate or interact with each other.

Thus, while there has been described what are believed to be the preferred embodiments of the invention, those skilled in the art will recognize that other and further modifications may be made thereto without departing from the spirit of the invention, and it is intended to claim all such changes and modifications as fall within the scope of the invention. For example, any formulas given above are merely representative of procedures that may be used. Functionality may be added or deleted from the block diagrams and operations may be interchanged among functional blocks. Steps may be added or deleted to methods described within the scope of the present invention.

The claims defining the invention are as follows:

1. A device for processing audio data, the device including:
an input for receiving an audio signal, and based on the received audio signal providing an analogue electrical audio signal;
an ADC configured for converting the electrical analogue audio signal into a digital audio signal;
a processor configured to:
apply a time-to-frequency transformation to the digital audio signal, thereby to define a frequency domain signal;
modify the frequency domain signal based on a frequency mapping protocol, thereby to define a modified frequency domain signal;
apply a frequency-to-time transformation to the modified frequency domain signal, thereby to define a modified digital audio signal;
a DAC configured for converting the modified digital audio signal into a modified analogue audio signal; and
an output for providing the modified analogue audio signal.

2. A device according to claim 1 wherein the input includes a transducer for receiving an acoustic signal and converting that to an electrical analogue audio signal.

3. A device according to claim 1 wherein the input includes an input for receiving an electrical analogue audio signal from an external source.

4. A device according claim 1 wherein the output includes or is coupled to a speaker unit.

5. A device according to claim 4 including a body adapted for mounting to a human head such that the speaker unit is provided proximal the ear.

6. A device according to claim 4 wherein the output includes two speaker units, the device including a body adapted for mounting to a human head such that a speaker unit is provided proximal each ear.

7. A device according to claim 1 wherein the frequency mapping protocol defines a set of rules for modifying the behaviour of components of the frequency domain signal.

8. A device according to claim 7 wherein the frequency domain signal is split into a plurality of bands, each band corresponding to a frequency range, and the frequency mapping protocol defines rules for modifying the behaviour of frequency components of one or more of the bands.

9. A device according to claim 8 wherein the rules for modifying one or more of the bands includes a rule for mapping components of the frequency domain signal from a first band to a second band.

10. A device according to claim 8 wherein the rules for modifying one or more of the bands includes a rule for blocking components of the frequency domain signal that fall within a specified one or more bands.

11. A device according to claim 1 including an interface for allowing user modification of the frequency mapping protocol.

12. A device according to claim 11 wherein the interface includes a port for allowing connection of the device to an external device that executes a software application for allowing user modification of the frequency mapping protocol.

13. A device according to claim 11 including a memory unit for maintaining data indicative of the frequency mapping protocol, wherein the data indicative of the frequency mapping protocol is modified subject to user modification of the frequency mapping protocol.

14. A device according to claim 1 wherein the analogue audio signal is passed through a multiplexer, anti aliasing filter and/or programmable gain amplifier intermediate the input and the ADC.

15. A device according to claim 1 wherein the modified analogue audio signal is passed through a multiplexer, low pass filter and/or programmable gain amplifier intermediate the DAC and the output.

16. A method for controlling the processing of audio data, the method including:
(a) providing an interface for allowing a user to define rules for modifying the behaviour of audio data within a predefined selection of frequency bands;
(b) defining configuration data indicative of a frequency mapping protocol based on the rules defined at (a);
(c) providing a signal indicative of the configuration data for download to a device that processes audio data.

17. A device configured to:
receive an audio signal;
split the audio signal into frequency bands;
map one or more of the frequency bands to other frequency bands; and
provide an audio signal wherein the one or more of the frequency bands are mapped to other frequency bands.
